(19) United States
(12) Patent Application Publication
(10) Pub. No.: US 2025/0279144 A1
(43) Pub. Date: Sep. 4, 2025

(54) DYNAMIC REFERENCE CORRECTIVE READ

(71) Applicant: MICRON TECHNOLOGY, INC., Boise, ID (US)

(72) Inventor: Ching-Huang Lu, Fremont, CA (US)

(21) Appl. No.: 19/068,147

(22) Filed: Mar. 3, 2025

Related U.S. Application Data
(60) Provisional application No. 63/561,279, filed on Mar. 4, 2024.

(51) Int. Cl. G11C 16/34; G11C 16/08; G11C 29/52

(52) U.S. Cl. CPC G11C 16/3418; G11C 16/08; G11C 29/52; G11C 2207/2254

(57) ABSTRACT

A system includes a memory device and a processing device, operatively coupled with the memory device, to perform operations including: receiving a request to perform a read operation on a segment of the memory device; performing a distribution voltage measurement on at least two wordlines of the segment to obtain at least one delta voltage value; determining a corrective read offset based on the at least one delta voltage value; and performing a corrective read operation on the segment using the corrective read offset.

### RELATED APPLICATIONS

This application claims the benefit of U.S. Provisional Patent Application No. 63/561,279, filed Mar. 4, 2024, the entire contents of which are incorporated by reference herein.

### TECHNICAL FIELD

Embodiments of the disclosure relate generally to memory sub-systems, and more specifically, relate to dynamic reference corrective read.

### BACKGROUND

A memory sub-system can include one or more memory devices that store data. The memory devices can be, for example, non-volatile memory devices and volatile memory devices. In general, a host system can utilize a memory sub-system to store data at the memory devices and to retrieve data from the memory devices.

### BRIEF DESCRIPTION OF THE DRAWINGS

The disclosure will be understood more fully from the detailed description given below and from the accompanying drawings of various embodiments of the disclosure. The drawings, however, should not be taken to limit the disclosure to the specific embodiments, but are for explanation and understanding only.

FIG. 1 illustrates an example computing system that includes a memory sub-system, in accordance with some embodiments of the present disclosure.

FIG. 2 is a diagram of a segment of a memory device, in accordance with some embodiments of the present disclosure.

FIG. 3 is a flow diagram illustrating an example of methods to perform adaptive enhanced corrective read, in accordance with some embodiments of the present disclosure.

FIG. 4 illustrates an example of the distribution voltage measurement in the dynamic reference corrective read, in accordance with some embodiments of the present disclosure.

FIG. 5 is a block diagram of an example computer system in which embodiments of the present disclosure may operate.

### DETAILED DESCRIPTION

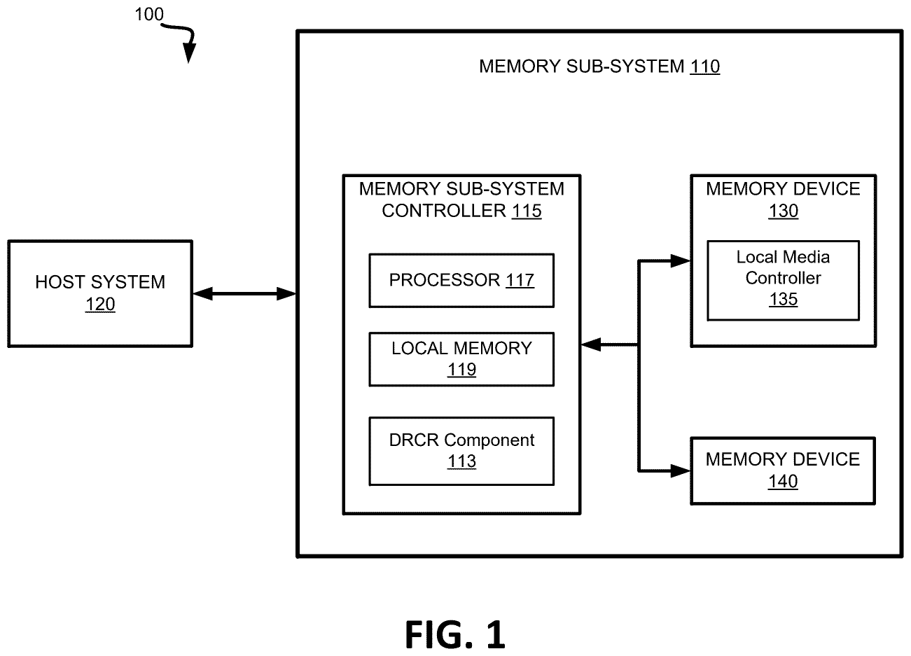

Aspects of the present disclosure are directed to dynamic reference corrective read. A memory sub-system can be a storage device, a memory module, or a combination of a storage device and memory module. Examples of storage devices and memory modules are described below in conjunction with FIG. 1. In general, a host system can utilize a memory sub-system that includes one or more components, such as memory devices that store data. The host system can provide data to be stored at the memory sub-system and can request data to be retrieved from the memory sub-system.

A memory sub-system can include high density non-volatile memory devices where retention of data is desired when no power is supplied to the memory device. One example of non-volatile memory devices is a negative-and (NAND) memory device. Other examples of non-volatile memory devices are described below in conjunction with FIG. 1. A non-volatile memory device is a package of one or more dies. Each die includes one or more planes. For some types of non-volatile memory devices (e.g., NAND devices), each plane includes a set of physical blocks. Each block consists of a set of pages. Each page includes a set of memory cells. A memory cell is an electronic circuit that stores information. Depending on the memory cell type, a memory cell can store one or more bits of binary information, and has various logic states that correlate to the number of bits being stored. The logic states can be represented by binary values, such as “0” and “1”, or combinations of such values.

A memory device can include multiple memory cells arranged in a two-dimensional or three-dimensional grid. Memory cells are formed onto a silicon wafer in an array of columns and rows. A memory device can further include conductive lines connected to respective ones of the memory cells, referred to as wordlines and bitlines. A wordline can refer to one or more rows of memory cells of the memory device and a bitline can refer to one or more columns of memory cells. The intersection of a bitline and wordline constitutes the address of the memory cell. A block hereinafter refers to a unit of the memory device used to store data and can include a group of memory cells, a wordline group, a wordline, or individual memory cells. One or more blocks can be grouped together to form a plane of the memory device in order to allow concurrent operations to take place on each plane. The memory device can include circuitry that performs concurrent memory page accesses of two or more memory planes. For example, the memory device can include a respective access line driver circuit and power circuit for each plane of the memory device to facilitate concurrent access of pages of two or more memory planes, including different page types.

A memory cell (“cell”) can be programmed (written to) by applying a certain voltage to the cell, which results in an electric charge being held by the cell. For example, a voltage signal V_{CG} that can be applied to a control electrode of the cell to open the cell to the flow of electric current across the cell, between a source electrode and a drain electrode. More specifically, for each individual cell (having a charge Q stored thereon) there can be a threshold control gate voltage VT (also referred to as the “threshold voltage”) such that the source-drain electric current is low for the control gate voltage (V_{CG}) being below the threshold voltage, V_{CG}<V_{T}. The current increases substantially once the control gate voltage has exceeded the threshold voltage, V_{CG}>V_{T}. Because the actual geometry of the electrodes and gates varies from cell to cell, the threshold voltages can be different even for cells implemented on the same die. The cells can, therefore, be characterized by a distribution P of the threshold voltages, P (Q,V_{T})=dW/dV_{T}, where dW represents the probability that any given cell has its threshold voltage within the interval [V_{T}, V_{T}+dV_{T}] when charge Q is placed on the cell.

A memory device can exhibit threshold voltage distributions P (Q,V_{T}) that are narrow compared with the working range of control voltages tolerated by the cells of the device. Accordingly, multiple non-overlapping distributions P (Qₖ, V_{T}) can be fit into the working range allowing for storage and reliable detection of multiple values of the charge Qₖ, k=1, 2, 3 . . . . A valley can refer to an area or a region between a pair of adjacent programming distributions. Valleys are interspersed with voltage intervals (“valley margins”) where none (or very few) of the cells of the device have their threshold voltages. Such valley margins can, therefore, be used to separate various charge states Qₖ—the logical state of the cell can be determined by detecting, during a read operation, between which two valley margins the respective threshold voltage V_{T} of the cell resides. Specifically, the read operation can be performed by comparing the measured threshold voltage V_{T} exhibited by the memory cell to one or more reference voltage levels corresponding to known valley margins (e.g., centers of the margins) of the memory device (“read level threshold”).

One type of cell is a single level cell (SLC), which stores 1 bit per cell and defines 2 logical states (“states”) (“1” or “L0” and “0” or “L1”) each corresponding to a respective V_{T} level. For example, the “1” state can be an erased state and the “0” state can be a programmed state (L1). Another type of cell is a multi-level cell (MLC), which stores 2 bits per cell and defines 4 states (“11” or “L0”, “10” or “L1”, “01” or “L2” and “00” or “L3”) each corresponding to a respective V_{T} level. For example, the “11” state can be an erased state and the “01”, “10” and “00” states can each be a respective programmed state. Another type of cell is a triple level cell (TLC), which stores 3 bits per cell and defines 8 states (“111” or “L0”, “110” or “L1”, “101” or “L2”, “100” or “L3”, “011” or “L4”, “010” or “L5”, “001” or “L6”, and “000” or “L7”) each corresponding to a respective V_{T} level. For example, the “111” state can be an erased state and each of the other states can be a respective programmed state. Another type of a cell is a quad-level cell (QLC), which stores 4 bits per cell and defines 16 states L0-L15, where L0 corresponds to “1111” and L15 corresponds to “0000”. Another type of cell is a penta-level cell (PLC), which stores 5 bits per cell and defines 32 states. Other types of cells are also contemplated. Thus, an n-level cell can use 2ⁿ levels of charge to store n bits. A memory device can include one or more arrays of memory cells such as SLCs, MLCs, TLCs, QLCs, PLCs, etc. or any combination of such. For example, a memory device can include an SLC portion, and an MLC portion, a TLC portion, a QLC portion, or a PLC portion of cells.

A valley margin can also be referred to as a read window. For example, in a SLC cell, there is 1 read window that exists with respect to the 2 Vₜ distributions. As another example, in an MLC cell, there are 3 read windows that exist with respect to the 4 Vₜ distributions. As yet another example, in a TLC cell, there are 7 read windows that exist with respect to the 8 Vₜ distributions. Read window size generally decreases as the number of states increases. For example, the 1 read window for the SLC cell may be larger than each of the 3 read windows for the MLC cell, and each of the 3 read windows for the MLC cell may be larger than each of the 7 read windows for the TLC cell, etc. Read window budget (RWB) refers to the cumulative value of the read windows.

While the threshold voltage is initially set at a certain target value, numerous factors including a number of program/erase cycles performed on the memory device, temperature changes, etc., can cause the threshold voltage to increase or decrease over time. This shift away from the target value can lead to charge loss, causing the memory device to function improperly and potentially causing reliability problems in the data stored on the wordlines of the corresponding sub-block. Depending on the variation of stored memory cell charges between adjacent wordlines, an electrical field of the memory cells could drive the stored electrons from high concentration to low concentration and/or into the spacing between wordlines. This redistribution of stored electrons may result in a downshift for high voltage states and an upshift for low voltage states, which can be referred to as lateral charge migration. Lateral charge migration may be caused by cell-to-cell interference that exists in a memory array between the target cells and their respective groups of adjacent cells. The lateral charge migration, in addition to intrinsic charge loss, can further lead to a widening of V_{T} distributions. The V_{T} distribution widening can cause RWB degradation, which can negatively affect memory device reliability. For example, RWB degradation can lead to an increase in the number of errors (e.g., bit errors) and/or error rate (e.g., bit error rate (BER)).

One mechanism to compensate for the effects of lateral charge migration is to perform a corrective read operation. Generally, a corrective read operation is performed to read each target cell using an appropriate read level offset that accounts for the lateral charge migration and/or intrinsic charge loss caused by the respective group of adjacent cells. The read level offset can be applied with respect to a center read level. For example, the center read level can be located within a valley between target cell V_{T} distributions.

To implement a corrective read operation, a controller can, for each group of adjacent cells, obtain cell state information for each cell of the group of adjacent cells. The cell state information for a cell reflects the logical level (e.g., L0-Ln, where n is the total number of logical levels supported) of the cell. For example, if a cell is an SLC cell, the cell state information can reflect whether the cell is in the L0 state or the L1 state. As another example, if the cell is a TLC cell, the cell state information can reflect which of the states L0-L7 that the cell is in. The cell state information for a cell can be obtained by identifying the state of the cell.

To identify the state of the cell, the controller can cause a read voltage to be applied to the cell (e.g., gate electrode of the cell) and determine whether the read voltage activates (e.g., turns on) the cell. If the read voltage activates the cell, this indicates that the read voltage is greater than or equal to the V_{T} of the cell. Additional read voltage(s) may be applied to the cell to determine whether the cell is in a lower state. If the read voltage does not activate the cell, this means that the read voltage is less than the V_{T} of the cell, and that the cell is in a higher state. Additional read voltage(s) may be applied until the cell is activated. For each group of adjacent cells, the controller can store the cell state information for each cell of the group of adjacent cells in a respective page buffer (e.g., static page buffer). Each page buffer can be connected to a respective group of adjacent cells via a bitline.

In some embodiments, the cell state information for each cell of a group of adjacent cells is 1-bit information. For example, obtaining the 1-bit cell state information can involve applying a single strobe read to each cell of the group of adjacent cells. If the group of adjacent cells includes a single cell (e.g., a cell connected to one of the adjacent wordlines WLₙ₋₁ and WLₙ₊₁), then the stored cell state information is 1 bit in total. The 1-bit stored cell state information can be used to implement 1-bit corrective read (1BCR). If the group of adjacent cells includes a pair of cells (e.g., cells connected to the adjacent wordlines WLₙ₋₁ and WLₙ₊₁), then the stored cell state information is 2 bits in total. The 2 bit stored cell state information can be used to implement a “1-bit 2-sided” version of 2-bit corrective read (2BCR).

In some embodiments, the cell state information for each cell of a group of adjacent cells is 2-bit information. For example, obtaining the 2-bit cell state information can involve applying a three strobe read to each cell of the group of adjacent cells. If the group of adjacent cells includes a single adjacent cell (e.g., a cell connected to one of the adjacent wordlines WLₙ₋₁ and WLₙ₊₁), then the stored cell state information is 2 bits in total. The 2 bit stored cell state information can be used to implement a “2-bit 1-sided” version of 2BCR. If the group of adjacent cells includes a pair of cells (e.g., cells connected to the adjacent wordlines WLₙ₋₁ and WLₙ₊₁), then the stored cell state information is 4 bits in total. The 4 bit stored cell state information can be used to implement 4-bit corrective read (4BCR).

In conventional systems, the corrective read functionality can be turned on or off by a user, for example, in an error handling flow list, and can use default values (e.g., through a predetermined lookup table) for certain parameters in a given system. However, such corrective read typically does not consider the duration of data retention and the program/erase cycles that are present in the memory sub-system. In conventional memory sub-systems, the longer the data written to a memory component remains stagnant (e.g., not refreshed and/or rewritten) in the memory component (e.g., baking) and/or the more the program/erase cycles are completed, the more data within the memory component degrades. Due to the data remaining stagnant in the memory component and degrading overtime, the lateral charge migration increases when performing read operations using the calibrated read level trim to read the data from the memory component. Thus, using the predetermined constant values of read voltage offsets, the memory component containing the data can be over-compensated or under-compensated, which can result in reduced performance of the memory device, and can affect the quality of service of the memory device.

In some implementations, each block can include a number of sub-blocks, where each sub-block is defined by an associated pillar (e.g., a vertical conductive line) extending from a shared bitline. For example, the sub-blocks can be accessed separately (e.g., to perform program or read operations) to selectively enable the pillar associated with a certain sub-block, while disabling the pillars associated with other sub-blocks. Due to the operation difference, the lateral charge migration can vary across the pillars. The conventional corrective read has failed to consider the cross-pillar variation of the lateral charge migration.

Aspects of the present disclosure address the above and other deficiencies by implementing a dynamic reference corrective read technique that determines a corrective read offset referencing a distribution voltage measurement of wordlines dynamically at the time of performing the corrective read operation. As opposed to the predetermined constant offsets utilized in some implementations of corrective read, the corrective read offsets described herein can be determined on-the-fly dynamically. Thus, the dynamic reference corrective read can result in improved read performance.

Specifically, the memory sub-system controller may receive a read request on a segment of a memory device. As an illustrative example, a memory device (e.g., a three-dimensional (3D) cross-point device) can include multiple segments, where each segment can include one or more decks. A deck can be defined as a two-dimensional (2D) array of memory cells electronically addressable by a vertical access line(s) (e.g., wordline(s)), and multiple decks can be stacked within a memory device (e.g., stacked vertically). The read request may specify the wordlines(s) (referred to as selected wordline(s)) on which the read operation is to be performed. The memory sub-system controller may initiate the read operation and, in response, detect a read error over one or more memory cells in the selected wordline(s). The memory sub-system controller may trigger an error handling flow responsive to the error detection. Upon triggering the error handling flow, the memory sub-system controller may perform a calibration measurement on the segment of the memory device. For example, the memory sub-system controller may perform a calibration measurement of a center of a voltage distribution valley for each state of each cell in the segment of the memory device) to keep each read level threshold centered so that the memory device can achieve the best overall bit error rate (BER) possible.

The memory sub-system controller may then determine two adjacent edge wordlines in the same deck as the selected wordline(s). In some implementations, a first edge wordline of two adjacent edge wordlines is the top wordline adjacent to (e.g., physically located below) a dummy wordline (i.e., a wordline in an erased state), and a second edge wordline of two adjacent edge wordlines is the wordline adjacent to (e.g., physically located below) the first edge wordline. The memory sub-system controller may reference these two adjacent edge wordlines to determine a corrective read offset. Specifically, the memory sub-system controller may perform a distribution voltage measurement on each of two wordlines by measuring a voltage value of a threshold voltage distribution for the wordline. In one example, the voltage value may fall within a particular one of the threshold voltage distributions corresponding to a state (e.g., L0-Ln, where n is the total number of logical levels supported) of the wordline, and the voltage value corresponds to a voltage in an upper tail of the state in the voltage distribution that satisfies a threshold criterion. (In some cases, using a voltage in the upper tail is most effective when reading the highest state in the voltage distributions.) In one implementation, the voltage value satisfying the threshold criterion may be a minimum voltage to conduct the bitlines at a failed bit count (CFBit) value. The failed bit count (CFBit) value reflects (i.e., is equal to or is derived by a known transformation from) the number of non-conducting bitlines. For example, the CFBit value may be N, and the voltage value satisfying the threshold criterion may be a minimum voltage to conduct all bitlines except N bitlines. As a result, the memory sub-system controller may obtain a voltage value on each of these two wordlines and determine a delta voltage value (e.g., a first delta voltage value) by calculating the difference of these two voltage values. The memory sub-system controller may use the delta voltage value to determine a corrective read offset via a predetermined lookup table or an equation, and perform a corrective read operation using the corrective read offset.

In some implementations, the memory sub-system controller may, alternatively or additionally, perform a distribution voltage measurement on the selected wordline to obtain another voltage value. The processing logic may determine another delta voltage value (e.g., a second delta voltage value) by calculating the difference between the voltage value of the selected wordline and the voltage value of one of the edge wordlines. The memory sub-system controller may use, for example, the first delta voltage value and the second delta voltage value, to determine a corrective read offset via another predetermined lookup table or another equation, and perform a corrective read operation using the corrective read offset. As such, the dynamic reference corrective read can be used to mitigate the lateral charge migration caused by cross-pillar variation.

Advantages of the present disclosure include, but are not limited to, improved memory device performance and reliability. For example, implementing dynamic reference corrective read can improve read accuracy based on the edge wordline difference, which reduces read errors, reduces the latency degradation, reduces trigger rate disk, and increases the life of a memory device. Specifically, implementing dynamic reference corrective read can mitigate the lateral charge migration. In addition, the dynamic reference corrective read can be used in any of 1BCR, 2BCR, 4BCR, etc.

FIG. 1 illustrates an example computing system 100 that includes a memory sub-system 110 in accordance with some embodiments of the present disclosure. The memory sub-system 110 can include media, such as one or more volatile memory devices (e.g., memory device 140), one or more non-volatile memory devices (e.g., memory device 130), or a combination of such.

A memory sub-system 110 can be a storage device, a memory module, or a combination of a storage device and memory module. Examples of a storage device include a solid-state drive (SSD), a flash drive, a universal serial bus (USB) flash drive, an embedded Multi-Media Controller (eMMC) drive, a Universal Flash Storage (UFS) drive, a secure digital (SD) card, and a hard disk drive (HDD). Examples of memory modules include a dual in-line memory module (DIMM), a small outline DIMM (SO-DIMM), and various types of non-volatile dual in-line memory modules (NVDIMMs).

The computing system 100 can be a computing device such as a desktop computer, laptop computer, network server, mobile device, a vehicle (e.g., airplane, drone, train, automobile, or other conveyance), Internet of Things (IoT) enabled device, embedded computer (e.g., one included in a vehicle, industrial equipment, or a networked commercial device), or such computing device that includes memory and a processing device.

The computing system 100 can include a host system 120 that is coupled to one or more memory sub-systems 110. In some embodiments, the host system 120 is coupled to multiple memory sub-systems 110 of different types. FIG. 1 illustrates one example of a host system 120 coupled to one memory sub-system 110. As used herein, “coupled to” or “coupled with” generally refers to a connection between components, which can be an indirect communicative connection or direct communicative connection (e.g., without intervening components), whether wired or wireless, including connections such as electrical, optical, magnetic, etc.

The host system 120 can include a processor chipset and a software stack executed by the processor chipset. The processor chipset can include one or more cores, one or more caches, a memory controller (e.g., NVDIMM controller), and a storage protocol controller (e.g., PCIe controller, SATA controller). The host system 120 uses the memory sub-system 110, for example, to write data to the memory sub-system 110 and read data from the memory sub-system 110.

The host system 120 can be coupled to the memory sub-system 110 via a physical host interface. Examples of a physical host interface include, but are not limited to, a serial advanced technology attachment (SATA) interface, a peripheral component interconnect express (PCIe) interface, universal serial bus (USB) interface, Fibre Pillar, Serial Attached SCSI (SAS), a double data rate (DDR) memory bus, Small Computer System Interface (SCSI), a dual in-line memory module (DIMM) interface (e.g., DIMM socket interface that supports Double Data Rate (DDR)), etc. The physical host interface can be used to transmit data between the host system 120 and the memory sub-system 110. The host system 120 can further utilize an NVM Express (NVMe) interface to access components (e.g., memory devices 130) when the memory sub-system 110 is coupled with the host system 120 by the physical host interface (e.g., PCIe bus). The physical host interface can provide an interface for passing control, address, data, and other signals between the memory sub-system 110 and the host system 120. FIG. 1 illustrates a memory sub-system 110 as an example. In general, the host system 120 can access multiple memory sub-systems via a same communication connection, multiple separate communication connections, and/or a combination of communication connections.

The memory devices 130, 140 can include any combination of the different types of non-volatile memory devices and/or volatile memory devices. The volatile memory devices (e.g., memory device 140) can be, but are not limited to, random access memory (RAM), such as dynamic random access memory (DRAM) and synchronous dynamic random access memory (SDRAM).

Some examples of non-volatile memory devices (e.g., memory device 130) include a negative-and (NAND) type flash memory and write-in-place memory, such as a three-dimensional cross-point (“3D cross-point”) memory device, which is a cross-point array of non-volatile memory cells. A cross-point array of non-volatile memory cells can perform bit storage based on a change of bulk resistance, in conjunction with a stackable cross-gridded data access array. Additionally, in contrast to many flash-based memories, cross-point non-volatile memory can perform a write in-place operation, where a non-volatile memory cell can be programmed without the non-volatile memory cell being previously erased. NAND type flash memory includes, for example, two-dimensional NAND (2D NAND) and three-dimensional NAND (3D NAND).

Each of the memory devices 130 can include one or more arrays of memory cells. One type of memory cell, for example, single level memory cells (SLC) can store one bit per memory cell. Other types of memory cells, such as multi-level memory cells (MLCs), triple level memory cells (TLCs), quad-level memory cells (QLCs), and penta-level memory cells (PLCs) can store multiple bits per memory cell. In some embodiments, each of the memory devices 130 can include one or more arrays of memory cells such as SLCs, MLCs, TLCs, QLCs, PLCs or any combination of such. In some embodiments, a particular memory device can include an SLC portion, and an MLC portion, a TLC portion, a QLC portion, or a PLC portion of memory cells. The memory cells of the memory devices 130 can be grouped as pages that can refer to a logical unit of the memory device used to store data. With some types of memory (e.g., NAND), pages can be grouped to form blocks.

Although non-volatile memory components such as a 3D cross-point array of non-volatile memory cells and NAND type flash memory (e.g., 2D NAND, 3D NAND) are described, the memory device 130 can be based on any other type of non-volatile memory, such as read-only memory (ROM), phase change memory (PCM), self-selecting memory, other chalcogenide based memories, ferroelectric transistor random-access memory (FeTRAM), ferroelectric random access memory (FeRAM), magneto random access memory (MRAM), Spin Transfer Torque (STT)-MRAM, conductive bridging RAM (CBRAM), resistive random access memory (RRAM), oxide based RRAM (OxRAM), negative-or (NOR) flash memory, or electrically erasable programmable read-only memory (EEPROM).

A memory sub-system controller 115 (or controller 115 for simplicity) can communicate with the memory devices 130 to perform operations such as reading data, writing data, or erasing data at the memory devices 130 and other such operations. The memory sub-system controller 115 can include hardware such as one or more integrated circuits and/or discrete components, a buffer memory, or a combination thereof. The hardware can include a digital circuitry with dedicated (i.e., hard-coded) logic to perform the operations described herein. The memory sub-system controller 115 can be a microcontroller, special purpose logic circuitry (e.g., a field programmable gate array (FPGA), an application specific integrated circuit (ASIC), etc.), or other suitable processor.

The memory sub-system controller 115 can include a processing device, which includes one or more processors (e.g., processor 117), configured to execute instructions stored in a local memory 119. In the illustrated example, the local memory 119 of the memory sub-system controller 115 includes an embedded memory configured to store instructions for performing various processes, operations, logic flows, and routines that control operation of the memory sub-system 110, including handling communications between the memory sub-system 110 and the host system 120.

In some embodiments, the local memory 119 can include memory registers storing memory pointers, fetched data, etc. The local memory 119 can also include read-only memory (ROM) for storing micro-code. While the example memory sub-system 110 in FIG. 1 has been illustrated as including the memory sub-system controller 115, in another embodiment of the present disclosure, a memory sub-system 110 does not include a memory sub-system controller 115, and can instead rely upon external control (e.g., provided by an external host, or by a processor or controller separate from the memory sub-system).

In general, the memory sub-system controller 115 can receive commands or operations from the host system 120 and can convert the commands or operations into instructions or appropriate commands to achieve the desired access to the memory devices 130. The memory sub-system controller 115 can be responsible for other operations such as wear leveling operations, garbage collection operations, error detection and error-correcting code (ECC) operations, encryption operations, caching operations, and address translations between a logical address (e.g., a logical block address (LBA), namespace) and a physical address (e.g., physical block address) that are associated with the memory devices 130. The memory sub-system controller 115 can further include host interface circuitry to communicate with the host system 120 via the physical host interface. The host interface circuitry can convert the commands received from the host system into command instructions to access the memory devices 130 as well as convert responses associated with the memory devices 130 into information for the host system 120.

The memory sub-system 110 can also include additional circuitry or components that are not illustrated. In some embodiments, the memory sub-system 110 can include a cache or buffer (e.g., DRAM) and address circuitry (e.g., a row decoder and a column decoder) that can receive an address from the memory sub-system controller 115 and decode the address to access the memory devices 130.

In some embodiments, the memory devices 130 include local media controllers 135 that operate in conjunction with memory sub-system controller 115 to execute operations on one or more memory cells of the memory devices 130. An external controller (e.g., memory sub-system controller 115) can externally manage the memory device 130 (e.g., perform media management operations on the memory device 130). In some embodiments, memory sub-system 110 is a managed memory device, which is a raw memory device 130 having control logic (e.g., local controller 132) on the die and a controller (e.g., memory sub-system controller 115) for media management within the same memory device package. An example of a managed memory device is a managed NAND (MNAND) device.

The memory sub-system 110 includes a dynamic reference corrective read (DRCR) component 113 that can be used to implement the dynamic reference corrective read technique that determines a corrective read offset referencing a distribution voltage measurement of wordlines dynamically in accordance with embodiments of the present disclosure. In some embodiments, the memory sub-system controller 115 includes at least a portion of the DRCR component 113. In some embodiments, the DRCR component 113 is part of the host system 110, an application, or an operating system. In other embodiments, local media controller 135 includes at least a portion of DRCR component 113 and is configured to perform the functionality described herein.

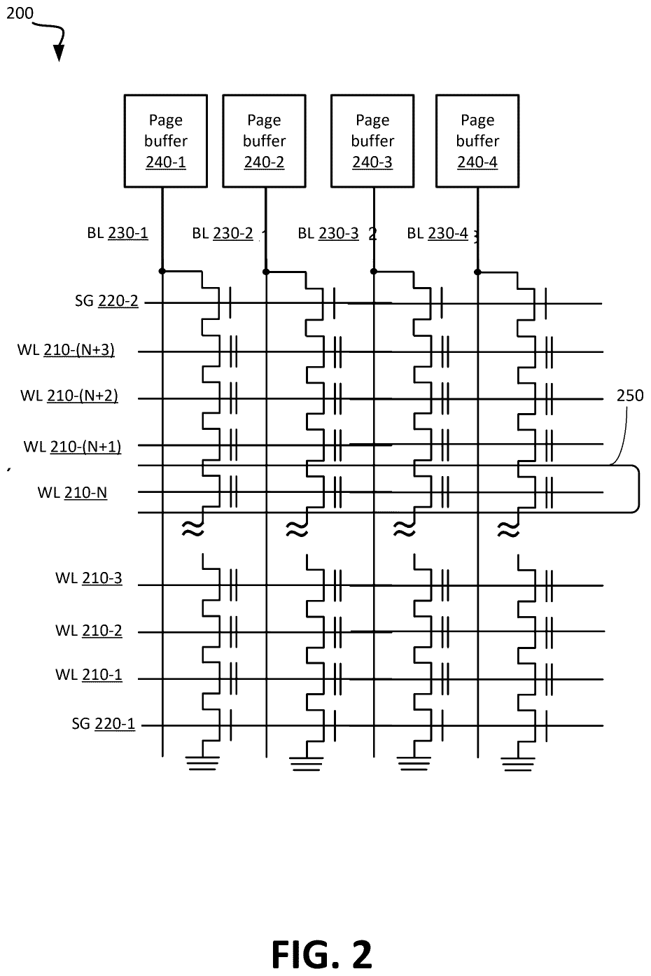

To perform a dynamic reference corrective read, the DRCR component 113 can receive a request to perform a read operation with respect to a set of target cells connected to a wordline, and, in response to receiving the request (e.g., read command), initiate the read operation via the local media controller 135 to read the set of target cells. The DRCR component 113 can perform a distribution voltage measurement on at least two wordlines of the segment to obtain at least one delta voltage value. The DRCR component 113 can determine a corrective read offset based on the at least one delta voltage value. The DRCR component 113 can then perform a corrective read operation using the determined corrective read offset. Further details regarding the operations of the DRCR component 113 will be described below with reference to FIGS. 2-5.

It will be appreciated by those skilled in the art that additional circuitry and signals can be provided, and that the components of FIG. 1 have been simplified. It should be recognized that the functionality of the various block components described with reference to FIG. 1 may not necessarily be segregated to distinct components or component portions of an integrated circuit device. For example, a single component or component portion of an integrated circuit device could be adapted to perform the functionality of more than one block component of FIG. 1. Alternatively, one or more components or component portions of an integrated circuit device could be combined to perform the functionality of a single block component of FIG. 1.

FIG. 2 is a diagram of a portion of a memory array 200, in accordance with some embodiments. The memory array 200 can include any suitable number of wordlines (WLs). For example, as shown, the memory array 200 includes a number of wordlines WL 210-1 through WL 210-(N+3). Each of the WLs 210-1 through 210-(N+3) is connected to a respective set of cells. Each of the WLs 210-1 through 210-(N+3) is adjacent to at least one WL. For example, WL 210-(N+3) and WL 210-(N+1) are each adjacent wordlines with respect to WL 210-N+2. The memory array 200 further includes select gate (SG) 220-1 and SG 220-2 In some embodiments, SG 220-1 is a source-side SG (SGS) and SG 220-2 is a drain-side SG (SGD).

The memory array 200 further includes a number of bitlines (BLs) including BL 230-1 through 230-4 and a number of page buffers including page buffers 240-1 through 240-4. Each of the page buffers is connected to a respective one of the bitlines. Although only 4 bitlines 230-1 through 210-3 and page buffers 240-1 through 240-4 are shown, the memory array 200 can include any suitable number of bitlines and page buffers.

In this illustrative example, a set of target cells 250 is selected to be read. The set of target cells 250 includes a number of cells of the target wordline WL 210-N. Each target cell of the set of target cells 250 is adjacent to a pair of adjacent cells. More specifically, the pair of adjacent cells for a particular target cell includes the cell connected to WL 210-(N+1) that is directly above the target cell, and the cell connected to WL 210-(N−1) (not shown) that is directly below the target cell. That is, a target cell of the set of target cells 250 is connected to a same one of the bitlines as its respective pair of adjacent cells.

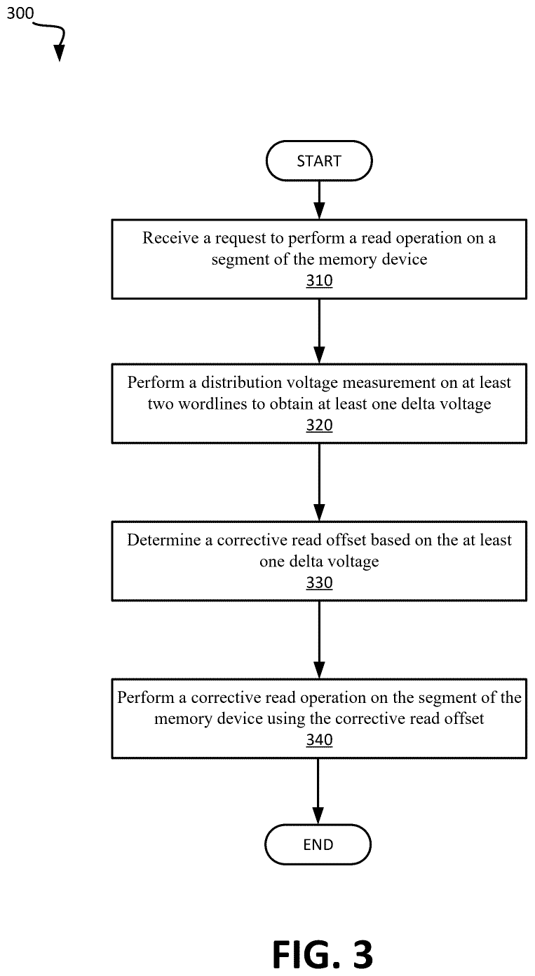

A memory sub-system controller (e.g., DRCR component 113 of FIG. 1) may receive a request to initiate a read operation with respect to the set of target cells 250 via a local media controller (e.g., local media controller 135 of FIG. 1). In one example, the wordline WL 210-(N+3) may be a wordline including a set of dummy cells in an erased state. The memory sub-system controller may determine two adjacent edge wordlines WL 210-(N+2) and WL 210-(N+1) and perform a distribution voltage measurement on each of wordlines WL 210-(N+2) and WL 210-(N+1). The memory sub-system controller may a distribution voltage measurement on wordline WL 210-N. The memory sub-system controller may obtain one or more delta voltage values using the result of distribution voltage measurements. The memory sub-system controller may determine a corrective read offset based on the delta voltage value(s) and perform, via the local media controller, the corrective read operation using the corrective read offset. Further details regarding performing adaptive enhanced corrective reads are described above with reference to FIG. 1 and will be described in further detail below with reference to FIGS. 3-5.

FIG. 3 is a flow diagram of an example method 300 to implement the dynamic reference corrective read, in accordance with some embodiments of the present disclosure. The method 300 can be performed by processing logic that can include hardware (e.g., processing device, circuitry, dedicated logic, programmable logic, microcode, hardware of a device, integrated circuit, etc.), software (e.g., instructions run or executed on a processing device), or a combination thereof. In some embodiments, the method 300 is performed by the DRCR component 113 of FIG. 1. Although shown in a particular sequence or order, unless otherwise specified, the order of the processes can be modified. Thus, the illustrated embodiments should be understood only as examples, and the illustrated processes can be performed in a different order, and some processes can be performed in parallel. Additionally, one or more processes can be omitted in various embodiments. Thus, not all processes are required in every embodiment. Other process flows are possible.

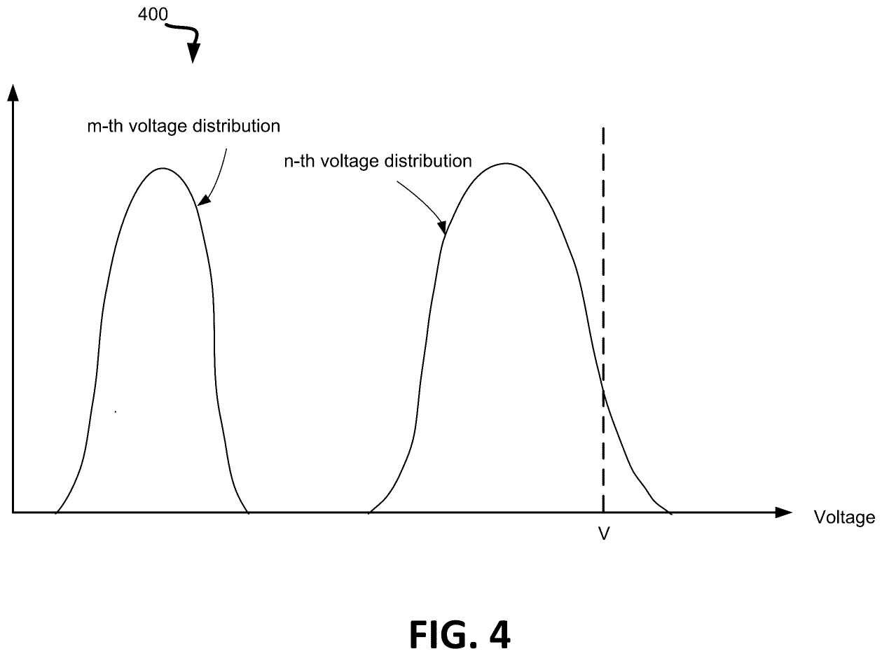

FIG. 4 is a diagram of an example distribution voltage measurement for the dynamic reference corrective read, in accordance with some embodiments of the present disclosure. Although shown in a particular value or range, the illustrated embodiments should be understood only as examples.

Referring now to FIG. 3, at operation 310, a request to perform a read operation on a segment of a memory device is received. The segment of the memory device may include one or more units of a memory array of a memory device, such as memory device 130. In one embodiment, the request can be a read command received at a memory sub-system controller (e.g., the memory sub-system controller 115 of FIG. 1). The processing logic may initiate a read operation with respect to a set of target cells in a wordline in response to receiving the request. The request may specify the wordline, for example, by including an address of the wordline. In one example, the processing logic may initiate the read operation and detect a read error in response to performing the read operation. In one example, the processing logic may initiate a corrective read operation with respect to a set of target cells in the wordline in response to receiving a request to perform a corrective read in response to detecting a read error. The request to perform a corrective read may be initiated as an option in an error-handling flow. In one example, the read error may be detected in response to performing a calibration operation.

In some implementations, the processing logic may receive a request to perform a read operation on a wordline of the segment of the memory device, where the wordline specified in the request can be referred to as a selected wordline. The processing logic may initiate a corrective read operation with respect to the selected wordline.

In some implementations, the processing logic may perform a calibration measurement of a center of a voltage valley for each state of each cell in the segment of the memory device. Performing the calibration measurement of a center of a voltage valley may use different measurement methods. Performing the calibration measurement provides appropriate read level adjustment to prevent significant errors that can occur due to charge change mechanisms such as disturbs, retention and SCL that can alter the data Vt voltage distributions stored in the cell. In some embodiments, the measurement method may be selected depending on a number of bits per cell which the segment of the memory device is configured to store. In some embodiments, the measurement method may be changed when the result of the calibration measurement is smaller than or equals to a certain value, such as from coarse calibration measurement to fine calibration measurement.

In some implementations, the measurement methods may include a continuous read level calibration (cRLC) operation, which is a read level calibration that can be performed to keep each read level threshold centered so that the memory component can achieve the best overall bit error rate (BER) possible. A memory cell (or memory component, etc.) that is calibrated or converged by cRLC has a center value that corresponds to a read level threshold (or read level trim) that is centered in or at a lowest point in the read threshold valley and results in a lowest bit error rate (BER). BER can refer to a ratio of a number of bits in error of a data vector divided by a total number of bits for the given data vector. A trim can refer to the digital value that is used for a circuit, such as a register, and that can be converted into an analog voltage value. For example, the read level threshold trims can be programmed into a read level threshold register, which produces a read level threshold voltage used to read data from a memory cell. The cRLC operation can be performed for each of the multiple read level threshold registers used during all read operations. The cRLC operation is referred to as continuous because the operation samples continually and dynamically at discrete intervals. For example, a sample, which can be a set of three reads, can be made at about 1 sample operation in every 1 to 30 seconds, depending on the requirements. Each sample initiated by the cRLC operation returns data for a particular die and a particular logical page type so that over many of these operations the information is aggregated and fed back in a closed loop system such that each die or read level threshold is kept calibrated (e.g., the read level threshold is centered). The read level thresholds of the memory component can start with manufacturing default read level thresholds. The cRLC operation can be run during a test mode so that all read level offset trims of all word line groups of all dies in the memory system are calibrated. As such, the cRLC operation is generally performed on all blocks of a memory system.

In some implementations, the measurement methods may include a coarse calibration method and a fine calibration method. In one illustrative example, the coarse calibration method may include a digital failed byte count (CFByte) coarse calibration. The failed byte count reflects (e.g., is equal to or is derived by a known transformation from) the number of bytes in the sensed data that have at least one non-conducting bitline. The CFByte value at a given read threshold voltage can have a strong correlation to the minimum valley location. In another illustrative example, the memory device can use a failed bit count (CFBit) coarse calibration. The failed bit count reflects (i.e., is equal to or is derived by a known transformation from) the number of non-conducting bitlines in the sensed data. For example, the memory device can inspect four or eight bitlines in a byte when counting non-conducting bitlines. In some embodiments, the control logic utilizes one or more measured metadata values to index within a lookup table that maps memory device-originated metadata values (e.g., failed byte counts or failed bit counts) to the read voltage adjustment values (e.g., read voltage offsets).

In some implementations, the fine calibration method may include a parallel auto-read calibration (pARC) technique. pARC can obtain the read level offset for multiple bitlines that are associated with a threshold voltage offset bin, and when applied to the base read level, minimizes error rates, i.e., there is no other threshold voltage offset set for a specific bin that results in lower error rates.

Performing the calibration measurement of a center of a voltage valley may involve repeating the calibration measurement until the result of the calibration measurement is less than or equal to a threshold value. This means that a value that is close enough to the center of the voltage valley has been found and is expected to be used for updating the respective offset in the threshold voltage offset bin. In one example, the calibration measurement may be performed repetitively so that the result of the calibration measurement decreases each time compared with a previous time (e.g., convergence).

In some implementations, the processing logic may determine at least two wordlines of the segment of the memory device. In some implementations, the request to perform the read operation specifies the selected wordline by including an address of the selected wordline, and the processing logic can determine two adjacent edge wordlines based on the address of the selected wordline. The processing logic can determine at least two wordlines as any two wordlines of: the two adjacent edge wordlines and the selected wordline. In some implementations, the processing logic may determine three wordlines including two adjacent edge wordlines and the selected wordline. For example, the processing logic can identify the deck mapped to the address of the selected wordline, and determine the wordline that is physically located below a dummy wordline of the deck is a first edge wordline, and the wordline physically located below the first edge wordline is a second edge wordline.

In some implementations, the processing logic may determine two adjacent edge wordlines as the two wordlines. Using FIG. 2 as an example, WL 210-(N+3) may be a dummy wordline, while WL 210-(N+2) and WL 210-(N+1) are the two adjacent edge wordlines.

In some implementations, the processing logic may determine one edge wordline and one selected wordline as the two wordlines. Using FIG. 2 as an example, WL 210-(N+3) may be a dummy wordline, while WL 210-(N+2) or WL 210-(N+1) is the edge wordline, and WL 210-N is the selected wordline.

At operation 320, the processing logic may perform a distribution voltage measurement on at least two wordlines to obtain at least one delta voltage value. Performing a distribution voltage measurement on a wordline may involve measuring a voltage value of a threshold voltage distribution for a wordline, and the voltage value may fall within a particular one of the threshold voltage distributions of a wordline, e.g., the m-th voltage distribution (or other designated voltage distribution) of a multiple-layer memory cell that can store a voltage that can represent several values corresponding to several voltage distributions. That is, the voltage value may fall within a range corresponding to a state (e.g., L0-Ln, where n is the total number of logical levels supported) of the wordline. The voltage value can be, for example, a voltage corresponding to a particular feature of the threshold voltage distribution of a wordline. The particular feature can be, for example, a characteristic of the voltage distribution, such as a peak, median, mean, mode, or certain threshold value of the voltage distribution. In some implementations, the voltage value corresponds to a voltage in an upper tail of a state in the voltage distribution that satisfies a threshold criterion. In some cases, using a voltage in the upper tail is most effective when reading the highest state in the voltage distributions. In one implementation, the voltage value satisfying the threshold criterion may be a minimum voltage to conduct the bitlines at a failed bit count (CFBit) value. The failed bit count (CFBit) value reflects (i.e., is equal to or is derived by a known transformation from) the number of non-conducting bitlines. For example, the CFBit value is N, and the voltage value satisfying the threshold criterion may be a minimum voltage to conduct all bitlines except N bitlines.

Referring to FIG. 4, the voltage value V can be understood as representing a “position” of a voltage distribution along the X-axis. The position can correspond to a feature of a particular voltage distribution, such as the n-th voltage distribution, of a wordline. The proceeding logic can measure the voltage value V as a value of a voltage satisfying a threshold criterion (e.g., a minimum voltage at which all bitlines except N bitlines are conducting).

In one example, the processing logic may perform a distribution voltage measurement on the first edge wordline to obtain a first voltage value; the processing logic may perform a distribution voltage measurement on the second edge wordline to obtain a second voltage value. The processing logic may determine a voltage offset value for the segment of the memory device by calculating a first value (Delta_1) of the first voltage value (V_{edge1}) above the second bit voltage (V_{edge2}): Delta_1=V_{edge2}−V_{edge1}.

In another example, the processing logic may perform a distribution voltage measurement on an edge wordline to obtain a first voltage value; the processing logic may perform a distribution voltage measurement on the selected wordline to obtain a second voltage value. The processing logic may determine a voltage offset value for the segment of the memory device by calculating a second value (Delta_2) of the first voltage value (V_{edge}) above the second voltage value (V_{select}): Delta=V_{edge}−V_{select}.

In yet another example, the processing logic may perform a distribution voltage measurement on the first edge wordline to obtain a first voltage value; the processing logic may perform a distribution voltage measurement on the second edge wordline to obtain a second voltage value; the processing logic may perform a distribution voltage measurement on the selected wordline to obtain a third voltage value. The processing logic may determine a first voltage offset value for the segment of the memory device by calculating a first value (Delta_1) of the first voltage value (V_{edge1}) above the second bit voltage (V_{edge2}): Delta_1=V_{edge2}−V_{edge1} and a second voltage offset value for the segment of the memory device by calculating a second value (Delta_2) of the second voltage value (V_{edge2}) above the third voltage value (V_{select}):Delta=V_{edge2}−V_{select}.

At operation 330, the processing logic may determine a corrective read offset based on the delta voltage value(s). As the voltage value changes over time and can correspond to an amount of voltage shift, the processing logic can use a particular delta voltage value to determine corrective read offset that is suitable for an amount of voltage shift that corresponds to the corrective read offset to mitigate the lateral charge migration.

In some implementations, the processing logic may determine a corrective read offset based on the delta voltage value(s) according to an equation. In one example, the processing logic may determine the corrective read offset by calculating the corrective read offset value: CRO=A*Delta_1, where A is a pre-determined value. In another example, the processing logic may determine the corrective read offset by calculating the corrective read offset value: CRO=B*Delta_2, where B is a pre-determined value. In yet another example, the processing logic may determine the corrective read offset by calculating the corrective read offset value: CRO=A*Delta_1+B*Delta_2, where A and B are pre-determined values. In some examples, B can be related to A, e.g., B=0.25 A.

In some implementations, the processing logic may determine a corrective read offset based on the delta voltage value(s) according to a predetermined lookup table. processing logic can find the corrective read offset values that correspond to a delta voltage value in a lookup table that maps delta voltage values to corresponding corrective read offset values. The lookup table can be generated from empirical data using a process that identifies delta voltage values that correspond to suitable corrective read offset values. In some embodiments, interpolation can be used to determine the corrective read offset for delta voltage values that are not present in the lookup table. If a delta voltage value is not in the lookup table, the memory sub-system controller can determine the corrective read offset values for the delta voltage value by interpolation between two chosen delta voltage values that are, respectively, greater than and less than the delta voltage value. The corrective read offset can be determined as an average of two chosen corrective read offset values, or a proportioned value between two chosen corrective read offset values.

At operation 340, the processing logic may perform a corrective read operation on the segment of the memory device using the corrective read offset. Instead of using a preset corrective read offset, the processing logic may perform a corrective read operation using the dynamically determined corrective read offset. To perform the corrective read operation, the processing logic causes a read voltage to be applied to one or more wordlines of the memory device. For example, the read voltage may equal or be derived from the default read level voltage modified by the corrective read offset.

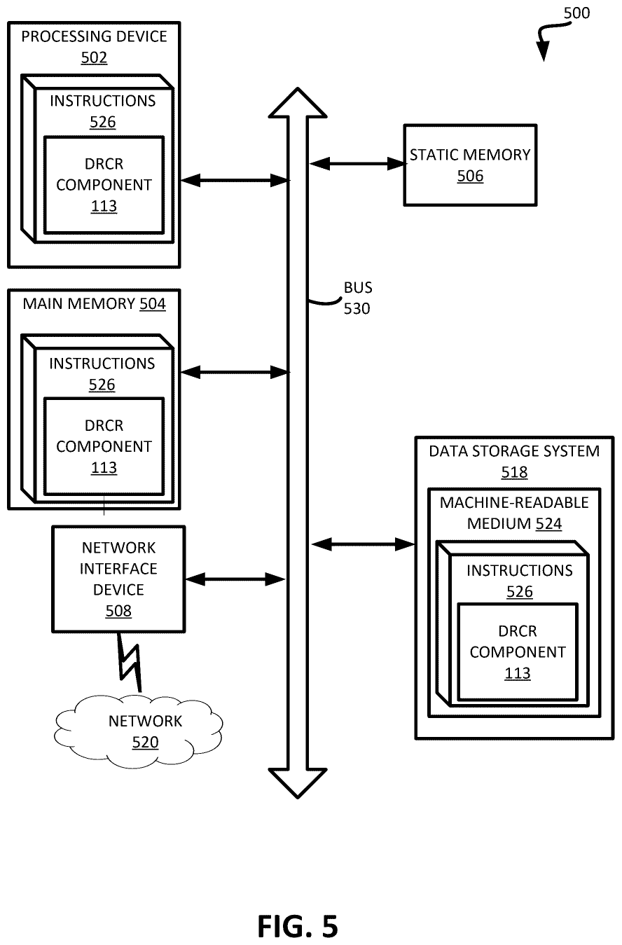

FIG. 5 illustrates an example machine of a computer system 500 within which a set of instructions, for causing the machine to perform any one or more of the methodologies discussed herein, can be executed. In some embodiments, the computer system 500 can correspond to a host system (e.g., the host system 120 of FIG. 1) that includes, is coupled to, or utilizes a memory sub-system (e.g., the memory sub-system 110 of FIG. 1) or can be used to perform the operations of a controller (e.g., to execute an operating system to perform operations corresponding to the DRCR component 113 of FIG. 1). In alternative embodiments, the machine can be connected (e.g., networked) to other machines in a LAN, an intranet, an extranet, and/or the Internet. The machine can operate in the capacity of a server or a client machine in client-server network environment, as a peer machine in a peer-to-peer (or distributed) network environment, or as a server or a client machine in a cloud computing infrastructure or environment.

The machine can be a personal computer (PC), a tablet PC, a set-top box (STB), a Personal Digital Assistant (PDA), a memory cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 500 includes a processing device 502, a main memory 504 (e.g., read-only memory (ROM), flash memory, dynamic random access memory (DRAM) such as synchronous DRAM (SDRAM) or RDRAM, etc.), a static memory 506 (e.g., flash memory, static random access memory (SRAM), etc.), and a data storage system 518, which communicate with each other via a bus 530.

Processing device 502 represents one or more general-purpose processing devices such as a microprocessor, a central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 502 can also be one or more special-purpose processing devices such as an application specific integrated circuit (ASIC), a field programmable gate array (FPGA), a digital signal processor (DSP), network processor, or the like. The processing device 502 is configured to execute instructions 526 for performing the operations and steps discussed herein. The computer system 500 can further include a network interface device 508 to communicate over the network 520.

The data storage system 518 can include a machine-readable storage medium 524 (also known as a computer-readable medium) on which is stored one or more sets of instructions 526 or software embodying any one or more of the methodologies or functions described herein. The instructions 526 can also reside, completely or at least partially, within the main memory 504 and/or within the processing device 502 during execution thereof by the computer system 500, the main memory 504 and the processing device 502 also constituting machine-readable storage media. The machine-readable storage medium 524, data storage system 518, and/or main memory 504 can correspond to the memory sub-system 110 of FIG. 1.

In one embodiment, the instructions 526 include instructions to implement functionality corresponding to a component (e.g., the DRCR component 113 of FIG. 1). While the machine-readable storage medium 524 is shown in an example embodiment to be a single medium, the term “machine-readable storage medium” should be taken to include a single medium or multiple media that store the one or more sets of instructions. The term “machine-readable storage medium” shall also be taken to include any medium that is capable of storing or encoding a set of instructions for execution by the machine and that cause the machine to perform any one or more of the methodologies of the present disclosure. The term “machine-readable storage medium” shall accordingly be taken to include, but not be limited to, solid-state memories, optical media, and magnetic media.

Some portions of the preceding detailed descriptions have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm is here, and generally, conceived to be a self-consistent sequence of operations leading to a desired result. The operations are those requiring physical manipulations of physical quantities. Usually, though not necessarily, these quantities take the form of electrical or magnetic signals capable of being stored, combined, compared, and otherwise manipulated. It has proven convenient at times, principally for reasons of common usage, to refer to these signals as bits, values, elements, symbols, characters, terms, numbers, or the like.

It should be borne in mind, however, that all of these and similar terms are to be associated with the appropriate physical quantities and are merely convenient labels applied to these quantities. The present disclosure can refer to the action and processes of a computer system, or similar electronic computing device, that manipulates and transforms data represented as physical (electronic) quantities within the computer system's registers and memories into other data similarly represented as physical quantities within the computer system memories or registers or other such information storage systems.

The present disclosure also relates to an apparatus for performing the operations herein. This apparatus can be specially constructed for the intended purposes, or it can include a general purpose computer selectively activated or reconfigured by a computer program stored in the computer. Such a computer program can be stored in a computer readable storage medium, such as any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various general purpose systems can be used with programs in accordance with the teachings herein, or it can prove convenient to construct a more specialized apparatus to perform the method. The structure for a variety of these systems will appear as set forth in the description below. In addition, the present disclosure is not described with reference to any particular programming language. It will be appreciated that a variety of programming languages can be used to implement the teachings of the disclosure as described herein.

The present disclosure can be provided as a computer program product, or software, that can include a machine-readable medium having stored thereon instructions, which can be used to program a computer system (or other electronic devices) to perform a process according to the present disclosure. A machine-readable medium includes any mechanism for storing information in a form readable by a machine (e.g., a computer). In some embodiments, a machine-readable (e.g., computer-readable) medium includes a machine (e.g., a computer) readable storage medium such as a read only memory (“ROM”), random access memory (“RAM”), magnetic disk storage media, optical storage media, flash memory components, etc.

In the foregoing specification, embodiments of the disclosure have been described with reference to specific example embodiments thereof. It will be evident that various modifications can be made thereto without departing from the broader spirit and scope of embodiments of the disclosure as set forth in the following claims. The specification and drawings are, accordingly, to be regarded in an illustrative sense rather than a restrictive sense.

What is claimed is:

1. A system comprising:
a memory device; and
a processing device, operatively coupled with the memory device, to perform operations comprising:
receiving a request to perform a read operation on a segment of the memory device;
performing a distribution voltage measurement on at least two wordlines of the segment to obtain at least one delta voltage value;
determining a corrective read offset based on the at least one delta voltage value; and
performing a corrective read operation on the segment using the corrective read offset.

2. The system of claim 1, wherein the operations further comprise:
performing a calibration measurement of a center of a voltage distribution valley for each state of each cell in the segment of the memory device.

3. The system of claim 2, wherein the calibration measurement comprises a coarse calibration and a fine calibration.

4. The system of claim 1, wherein the operations further comprise:
determining the at least two wordlines of the segment based on an address specified in the request.

5. The system of claim 1, wherein the at least two wordlines of the segment comprise two adjacent edge wordlines.

6. The system of claim 1, wherein the at least two wordlines of the segment comprise a wordline specified in the request and two adjacent edge wordlines.

7. The system of claim 1, wherein performing the distribution voltage measurement on the at least two wordlines further comprises obtaining a first voltage value on a first wordline of the at least two wordlines and a second voltage value on a second wordline of the at least two wordlines, wherein the at least one delta voltage value is a difference between the first voltage value and the second voltage value.

8. The system of claim 7, wherein each of the first voltage value and the second voltage value corresponds to a voltage of a state satisfying a failed bit count criterion.

9. The system of claim 1, wherein determining the corrective read offset based on the at least one delta voltage value comprises utilizing at least one of: a predefined lookup table or an equation.

10. The system of claim 1, wherein the operations further comprise:
determining whether the request triggers an error handling flow; and
responsive to determining that the request triggers the error handling flow, determining the at least two wordlines.

11. A method comprising:
receiving, by a processing device, a request to perform a read operation on a segment of a memory device;
performing a distribution voltage measurement on at least two wordlines of the segment to obtain at least one delta voltage value;
determining a corrective read offset based on the at least one delta voltage value; and
performing a corrective read operation on the segment using the corrective read offset.

12. The method of claim 11, further comprising:
performing a calibration measurement of a center of a voltage distribution valley for each state of each cell in the segment of the memory device.

13. The method of claim 12, wherein the calibration measurement comprises a coarse calibration and a fine calibration.

14. The method of claim 11, further comprising:
determining the at least two wordlines of the segment based on an address specified in the request.

15. The method of claim 11, wherein the at least two wordlines of the segment comprise two adjacent edge wordlines.

16. The method of claim 11, wherein the at least two wordlines of the segment comprise a wordline specified in the request and two adjacent edge wordlines.

17. The method of claim 11, wherein performing the distribution voltage measurement on the at least two wordlines further comprises obtaining a first voltage value on a first wordline of the at least two wordlines and a second voltage value on a second wordline of the at least two wordlines, wherein the at least one delta voltage value is a difference between the first voltage value and the second voltage value.

18. The method of claim 17, wherein each of the first voltage value and the second voltage value corresponds to a voltage of a state satisfying a failed bit count criterion.

19. The method of claim 11, wherein determining the corrective read offset based on the at least one delta voltage value comprises utilizing at least one of: a predefined lookup table or an equation.

20. A non-transitory computer-readable storage medium comprising instructions that, when executed by a processing device, cause the processing device to perform operations comprising:
receiving a request to perform a read operation on a segment of a memory device;
performing a distribution voltage measurement on at least two wordlines of the segment to obtain at least one delta voltage value;
determining a corrective read offset based on the at least one delta voltage value; and
performing a corrective read operation on the segment using the corrective read offset.
